(19) United States
(12) Patent Application Publication
(10) Pub. No.: US 2005/0162889 A1
(43) Pub. Date: Jul. 28, 2005

(54) Storage circuit, semiconductor device, electronic apparatus, and driving method

(76) Inventor: Mitsuhiro Yamamura, Suwa-shi (JP)

Correspondence Address: HARNESS, DICKEY & PIERCE, P.L.C., P.O. BOX 828, BLOOMFIELD HILLS, MI, 48303, US

(21) Appl. No.: 11/022,386

(22) Filed: Dec. 23, 2004

(30) Foreign Application Priority Data
Dec. 25, 2003 (JP) 2003-430674

(51) Int. Cl. G11C 11/22

(52) U.S. Cl. 365/145

(57) ABSTRACT

A storage circuit that is equipped with a storage section having a first ferroelectric capacitor and a second ferroelectric capacitor that are connected to each other in series, a potential difference generation section that gives a potential difference across both ends of the storage section, and a judging section that judges memory data stored in the storage section based on a potential at a connection node between the first ferroelectric capacitor and the second ferroelectric capacitor when the potential difference is given across the both ends. The judging section is preferably formed from an inverter that receives a potential at the connection node as an input.

### RELATED APPLICATIONS

This application claims priority to Japanese Patent Application No. 2003-430674 filed Dec. 25, 2003 which is hereby expressly incorporated by reference herein in its entirety.

### BACKGROUND

1. Technical Field

The present invention relates to storage circuits, semiconductor devices, electronic apparatuses, and driving methods. In particular, the present invention relates to storage circuits that can readily and stably read memory data, semiconductor elements and electronic apparatuses equipped with the storage circuits, and their driving methods.

2. Related Art

A conventional ferroelectric memory is disclosed in Japanese Laid-open Patent Application SHO 63-201998 (Patent Document 1). The ferroelectric memory disclosed in the aforementioned Patent Document 1 is equipped with a memory cell having a pair of ferroelectric capacitors that store complementary data, a pair of bit lines connected to the pair of ferroelectric capacitors, and a sense amplifier that responds to a inter-line potential difference between the pair of bit lines.

However, in the conventional ferroelectric memory described in the aforementioned Patent Document 1, because an operational amplifier is used as the sense amplifier, there is a problem in that the structure of the ferroelectric memory is complex.

Accordingly, it is an object of the present invention to provide storage circuits, semiconductor devices, electronic apparatuses, and driving methods which can solve the problems described above. This object can be achieved by combining the characteristics set forth in the independent claims in the scope of patent claims. Also, the dependent claims further define advantageous concrete examples of the present invention.

### SUMMARY

To achieve the object described above, in accordance with a first embodiment of the present invention, there is provided a storage circuit characterized in comprising: a storage section having a first ferroelectric capacitor and a second ferroelectric capacitor that are connected to each other in series; a potential difference generation section that gives a potential difference across both ends of the storage section; and a judging section that judges memory data stored in the storage section based on a potential at a connection node between the first ferroelectric capacitor and the second ferroelectric capacitor when the potential difference is given across the both ends. The judging section may preferably judge the memory data by comparing a potential in the middle of the potential difference and a potential at the connection node. Also, the first ferroelectric capacitor and the second ferroelectric capacitor may preferably store complementary data.

With the structure described above, depending on values of the memory data stored in the storage section, the potential at the connection node, when the potential difference generation section gives a potential difference across the two ends of the storage section, greatly changes. Accordingly, with the structure described above, with a very simple structure of judging a potential at the connection node, memory data stored in the storage section can be very stably judged.

The judging section may preferably have an inverter that receives the potential at the connection node as an input. With the structure described above, memory data can be stably judged, with a very simple structure.

The storage circuit may preferably be further equipped with a writing section that re-stores the memory data in the storage section, based on the memory data, by controlling the potentials on the two ends of the storage section and the connection node.

With the structure described above, when the judging section judges memory data stored in the storage section, even if the memory data is destroyed, data that is identical with the memory data can be stored in the storage section again. In other words, with the structure described above, the memory data is always stored in the storage section. Accordingly, even when the power supply that is fed to the storage circuit is cut off, the data remains to be stored in the storage section, such that the memory data can be re-supplied from the storage circuit to outside after feeding of the power supply starts again. Accordingly, with the structure described above, there can be provided a storage circuit whose operation is stable.

The writing section may preferably have a first inverter that receives the potential at the connection node as an input, and supplies an output to the two ends of the storage section, and a second inverter that inverts the output of the first inverter, and supplies the same to the input of the first inverter.

With the structure described above, potentials on the two ends of the storage section become to be generally the same potential as the potential on the output of the first inverter. Also, the potential at the connection node becomes to be generally the same potential as the potential on the input of the first inverter, in other words, on the output of the second inverter. Accordingly, with the structure described above, a potential difference can be provided between the two ends of the storage section and the connection node, and memory data stored in the storage section can be re-stored with a very simple structure.

The writing section may preferably be further equipped with a switch provided between the first inverter and the two ends of the storage section.

With the structure described above, the output of the first inverter can be electrically cut off from the two ends of the storage section. Accordingly, with the structure described above, potentials on the two ends of the storage section can be brought to a potential different from that on the output of the first inverter, such that a memory data judgment operation and re-storage operation can both be achieved.

The storage circuit may preferably be further equipped with a latch circuit that latches the memory data that is judged by the judging section.

With the structure described above, because memory data that has been judged by the judging section can be latched, the storage circuit can supply the memory data to outside even after the judging section has judged the memory data.

The storage circuit may preferably be further equipped with a discharge section that brings the two ends of the storage section and the connection node to an identical potential. In this case, the discharge section may preferably bring the two ends of the storage section and the connection node to a grounding potential.

With the structure described above, the potentials on the both ends of the ferroelectric capacitors can be brought to generally the same potential. Accordingly, a potential difference between the both ends of the ferroelectric capacitors can be reduced or brought to generally zero, such that static imprint of the ferroelectric capacitors can be suppressed.

The discharge section may preferably have a switch provided between the first inverter and the connection node.

With the structure described above, while memory data can be latched at the latch section, the potential at the connection node can be brought to the same potential as the potential on the two ends of the storage section.

In accordance with a second embodiment, there is provided a semiconductor device characterized in comprising the storage circuit described above. It is noted here that the semiconductor device generally refers to a device composed of semiconductor, which is quipped with a storage circuit in accordance with the present invention, and is not particularly limited in its structure, but may include storage devices, such as, for example, ferroelectric memory devices, DRAMs, flash memories and the like, which are quipped with the storage circuit described above, and all other devices that require storage circuits, such as, for example, logical devices, MPUs, and the like. The storage circuit may be implemented in a semiconductor device, for example, as a program circuit that reads memory data at a specified timing, such as, when the power supply is turned on, and continues outputting the memory data thereafter, a circuit for tuning IC characteristics, a re-configurable circuit, a redundant program circuit, and a nonvolatile logic circuit.

In accordance with a third embodiment, there is provided an electronic apparatus characterized in comprising the semiconductor device described above. It is noted here that the electronic apparatus generally refers to an apparatus equipped with a semiconductor device in accordance with the present invention, which achieves predetermined functions, and is not particularly limited in its structure, but may include all devices that require storage devices, such as, for example, computer devices in general, portable telephones, PHSs, PDAs, electronic notebooks, IC cards, and the like, which are equipped with the semiconductor device described above.

In accordance with a fourth embodiment of the present invention, there is provided a driving method for driving a storage circuit that is equipped with a storage section having a first ferroelectric capacitor and a second ferroelectric capacitor connected to each other in series, the driving method characterized in comprising: a step of giving a potential difference across both ends of the storage section; and a step of judging memory data stored in the storage section based on a potential at a connection node between the first ferroelectric capacitor and the second ferroelectric capacitor when the potential difference is given across the both ends.

Also, the driving method may preferably be further equipped with a step of re-storing the memory data in the storage section, based on the memory data judged, by controlling the potentials on the both ends of the storage section and the connection node.

### BRIEF DESCRIPTION OF THE DRAWINGS

FIG. 1 is a circuit diagram showing a first embodiment of a storage circuit 100 concerning embodiments of the present invention.

FIG. 2 is a diagram indicating operations of the storage circuit 100 in accordance with the first embodiment.

FIG. 3 is a diagram indicating hysteresis characteristics of a first ferroelectric capacitor 112 and a second ferroelectric capacitor 114.

FIG. 4 is a diagram showing a second embodiment of a storage circuit 100.

FIG. 5 is a diagram indicating operations of the storage circuit 100 in accordance with the second embodiment.

### DETAILED DESCRIPTION

The present invention is described below based on embodiments of the present invention with reference to the accompanying drawings. However, the embodiments described below do not limit the invention concerning the scope of patent claims, and all the combinations of the characteristics described in the embodiments would not necessarily be indispensable as the means for solution of the invention.

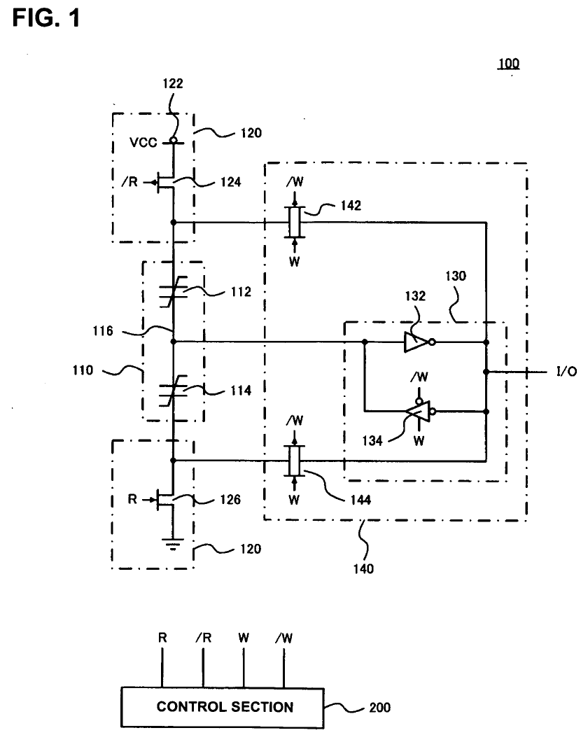

FIG. 1 is a circuit diagram showing a first embodiment example of a storage circuit 100 in accordance with an embodiment of the present invention. The storage circuit 100 has a structure equipped with a storage section 110, a potential difference generation section 120, a latch section 130, a writing section 140, an input/output terminal I/O, and a control section 200.

The storage section 110 is formed from a plurality of ferroelectric capacitors that are connected in series. In the present embodiment, the storage section 110 has a structure having a first ferroelectric capacitor 112 and a second ferroelectric capacitor 114. Each of the first ferroelectric capacitor 112 and the second ferroelectric capacitor 114 has one end and another end, and the other end of the first ferroelectric capacitor and the one end of the second ferroelectric capacitor are electrically connected at a connection node 116. Also, the one end of the first ferroelectric capacitor and the other end of the second ferroelectric capacitor compose an end section of the storage section 110, and the end section thereof is electrically connected to the potential difference generation section 120.

The potential difference generation section 120 is formed from a voltage source 122, a p-type MOS transistor 124, and an n-type MOS transistor 126, and gives a predetermined potential difference across two ends of the storage section 110. More specifically, the potential difference generation section 120 supplies a predetermined voltage to one end of the storage section 110, and grounds the other end thereof, thereby giving a potential difference between those predetermined voltages across the two ends of the storage section 110.

The voltage source 122 generates a voltage VCC for giving a potential difference between one end and the other end of the storage section 110, in other words, between one end of the first ferroelectric capacitor 112 and the other end of the second ferroelectric capacitor 114. The voltage source 122 may be, for example, a voltage source that is provided in a semiconductor device or the like in which the storage circuit 100 is implemented. Also, in the present embodiment, the potential difference generation section 120 supplies a voltage VCC to one end of the storage section 110, but may supply a voltage (VCC−Vth) which is a voltage reduced from the voltage VCC by a threshold voltage Vth of the MOS transistor, instead of the voltage VCC.

The p-type MOS transistor 124 has its source electrically connected to the voltage source 122, and its drain electrically connected to one end of the storage section 110. The p-type MOS transistor 124 switches, based on the potential on its gate, as to whether or not the voltage VCC is to be supplied to one end of the storage section 110. Also, the n-type MOS transistor 126 has its source grounded, and its drain electrically connected to the other end of the storage section 110. The n-type MOS transistor 126 switches, based on the potential on its gate, as to whether or not the other end of the storage section 110 is to be grounded. In other words, the potential difference generation section 120 controls, based on potentials (logical values) of control signals R and /R that are supplied to the gates of the p-type MOS transistor 124 and the n-type MOS transistor 126, as to whether the potential difference VCC is to be given across the two ends of the storage section 110. It is noted here that each control signal including a sign/is a signal in which the logical value of the control signal without including the sign/is inverted.

The latch circuit 130 is formed from a first inverter 132 and a second inverter 134, and based on a node potential that is the potential at the connection node 116, judges memory data stored in the storage section 110, and latches the memory data.

The first inverter 132 is an example of a judging section, receives a node potential as an input, and compares the node potential and an input threshold potential of the first inverter 132, thereby judging data stored in the storage section 110. More specifically, the first inverter 132 uses an input threshold potential that is a potential between the ground potential and VCC, judges as to whether the connection node is higher or lower than the reference potential, and outputs a data signal indicating the judgment result (in other words, stored data). In the present embodiment, the first inverter 132 outputs, as the data signal, a signal indicating a logical L or a logical H, when the connection node potential is higher or lower than the input threshold potential, respectively. Also, in the present embodiment, the input threshold potential of the first inverter 132 is a potential that is generally half the potential difference across the two ends of the storage section 110, in other words, a potential that is generally a half of VCC.

In the present embodiment, the first ferroelectric capacitor 112 and the second ferroelectric capacitor 114 have generally the same area, but in another embodiment, the first ferroelectric capacitor 112 and the second ferroelectric capacitor 114 may have mutually different areas. For example, when the voltage applied to the two ends of the storage section 110 is VCC−Vth, the area of the second ferroelectric capacitor 114 may be made greater than the area of the first ferroelectric capacitor 112 in order to set the input threshold voltage of the first inverter 132 at 1/2 VCC.

The second inverter 134 receives a data signal outputted from the first inverter 132, and generates an inversion data signal that is the data signal inverted. Also, the second inverter 134 has its input electrically connected to the first inverter 132, and its output electrically connected to the input of the first inverter 132 and the connection node 116, and supplies the inversion data signal to the input of the first inverter 132 and the connection node 116. By this, the first inverter 132 and the second inverter 134 compose a flip-flop, and the flip-flop latches the data signal.

Also, in the present embodiment, the second inverter 134 is a clocked gate inverter. The second inverter 134 is structured to output an inversion data signal when the logical value of the control signal W is a logical H, and provides an output of high impedance when the logical value of the control signal W is a logical L.

After the first inverter 132 that is an example of the judging section has judged memory data stored in the storage section 110, the writing section 140 stores the memory data in the storage section 110 again. The writing section 140 is formed from the first inverter 132, the second inverter 134, and transfer gates 142 and 144 which are an example of switches. In other words, in the present embodiment, the first inverter 132 composes a judging section, and a part of the writing section 140. Similarly, the second inverter 134 composes a part of the latch section 130, and a part of the writing section 140.

The transfer gate 142 is provided between the output of the first inverter 132 and one end of the storage section 110. The transfer gate 142 controls, based on potentials of the control signals W and /W supplied to its gate, as to whether or not the output of the first inverter 132 and the one end of the storage section 110 are to be electrically connected. In other words, the transfer gate 142 controls to bring the potential on the one end of the storage section 110 to the potential of the output of the first inverter 132, in other words, to the same potential as the potential of the data signal.

The transfer gate 144 is provided between the output of the first inverter 132 and the other end of the storage section 110. The transfer gate 142 controls, like the transfer gate 142, based on potentials of the control signals W and /W supplied to its gate, as to whether or not the output of the first inverter 132 and the other end of the storage section 110 are to be electrically connected.

In the present embodiment, the writing section 140 is formed from the transfer gates 142 and 144 that are an example of switches, but can be formed from n-type MOS transistors or p-type MOS transistors, instead of the transfer gates 142 and 144. In this case, a voltage VCC−Vth is supplied to the two ends of the storage section 110, instead of the voltage VCC. It is noted here that Vth is a threshold voltage of the n-type MOS transistor or the p-type MOS transistor.

The control section 200 generally controls operations of the storage circuit 100. In the present embodiment, the control section 200 generates control signals R and /R, and control signals W and /W, and supply them to the respective sections, thereby controlling the operations of the storage circuit 100.

The input/output terminal I/O outputs the data signal that is generated by the first inverter 132. Also, when predetermined memory data is stored in the storage section 110, as described below, the input/output terminal I/O receives the memory data from outside.

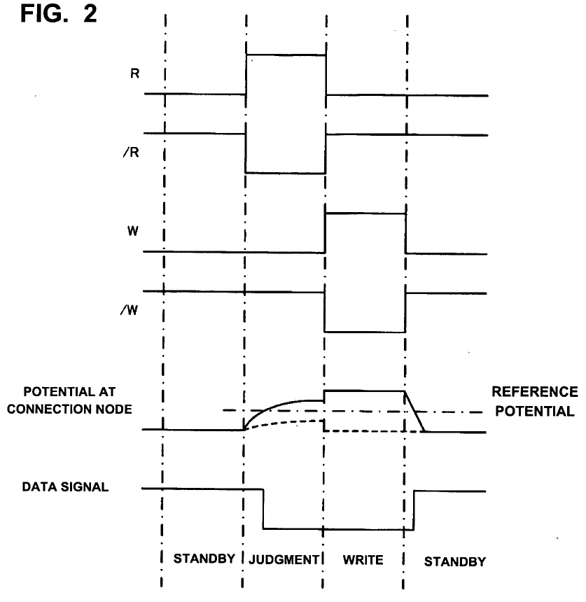

FIG. 2 is a timing chart indicating operations of the storage circuit 100 in accordance with the first embodiment. Referring to FIG. 1 and FIG. 2, operations of the storage circuit 100 of the present embodiment are described. In the present embodiment, it is assumed that the first ferroelectric capacitor 112 stores “1,” and the second ferroelectric capacitor 114 store “0.” In other words, the first ferroelectric capacitor 112 and the second ferroelectric capacitor 114 store complementary data. Also, in the present embodiment, the first ferroelectric capacitor 112 and the second ferroelectric capacitor 114 have generally the same hysteresis characteristics.

In a standby state, the control signals R and W indicate a logical L. In other words, the p-type MOS transistor 124, the n-type MOS transistor 126, and the transfer gates 142 and 144 are nonconductive, and the two ends of the storage section 110 are in a floating state, and their potentials become to be 0V due to natural discharge as described below. Also, the potential at the connection node 116, in other words, the potential on the input of the first inverter 132, is also naturally discharged to 0V, such that the logical value of the data signal indicates a logical H. Also, the output of the second inverter 134 is at high impedance, such that the connection node 116 is brought to a floating state with its potential remaining to be 0V.

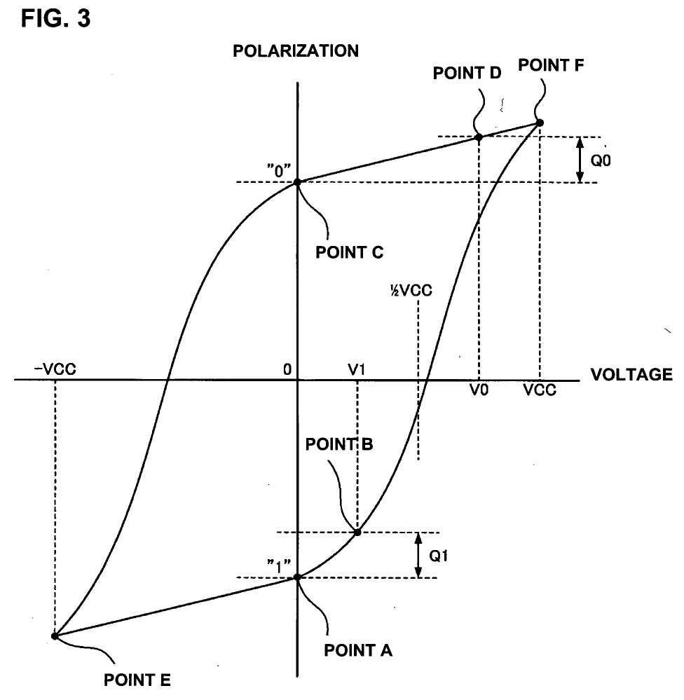

Next, memory data stored in the storage section 110 is judged. First, the control section 200 changes the control signal R to a logical H, thereby making the p-type MOS transistor 124 and the n-type MOS transistor 126 conductive. By this, the voltage VCC is supplied to one end of the first ferroelectric capacitor 112, and the other end of the second ferroelectric capacitor 114 is grounded. In other words, a potential difference VCC is given across the two ends of the storage section 110. Further referring to FIG. 3, changes in the potential at the connection node 116 which take place when the potential difference VCC is given across the two ends of the storage section 110 are described below.

FIG. 3 is a diagram indicating hysteresis characteristics of the first ferroelectric capacitor 112 and the second ferroelectric capacitor 114. In the figure, an axis of abscissas indicates voltages that are applied to both ends of the first ferroelectric capacitor 112 and/or the second ferroelectric capacitor 114, and an axis of ordinates indicates polarizations of the first ferroelectric capacitor 112 and/or the second ferroelectric capacitor 114. It is noted that, in the figure, when the potential on one end of the first ferroelectric capacitor 112 (or the second ferroelectric capacitor 114) is higher than the potential on the other end thereof, voltages are expressed in the positive side.

In a standby state, the potentials at the two ends of the storage section 110 and the connection node 116 are 0V, and therefore the potential difference across the both ends of the first ferroelectric capacitor 112 and the second ferroelectric capacitor 114 is generally zero, such that the hysteresis characteristic of the first ferroelectric capacitor 112 in which “1” is written is at point A, and the hysteresis characteristic of the second ferroelectric capacitor 114 in which “0” is written is at point C.

Then, when a potential difference VCC is given across the two ends of the storage section 110, positive voltages are applied to the two ends of the first ferroelectric capacitor 112 and the second ferroelectric capacitor 114, respectively, such that the hysteresis characteristics that have been at point A and point C shift in the rightward direction of the figure. In this instance, in the present embodiment, a voltage V1 that is applied to the first ferroelectric capacitor 112, a charge amount Q1 retrieved from the first ferroelectric capacitor 112, a voltage V0 that is applied to the second ferroelectric capacitor 114, and a charge amount Q0 that is retrieved from the second ferroelectric capacitor 114 satisfy the following relation:
Q0=Q1
V0+V1=VCC

Therefore,
V0>V1
V0>1/2VCC, V1<1/2VCC

Accordingly, in the present embodiment, when the potential difference VCC is given across the two ends of the storage section 110, the potential at the connection node 116 rises to V0 (see FIG. 2). On the other hand, in reverse of the present embodiment, when “0” is written in the first ferroelectric capacitor 112, and “1” is written in the second ferroelectric capacitor 114, and when the potential difference VCC is given across the two ends of the storage section 110, the potential at the connection node 116 rises to V1 (see dotted lines in FIG. 2).

Then, the first inverter 132 compares the potential at the connection node 116 that has risen with the input threshold potential of the first inverter 132, thereby judging memory data stored in the storage section 110. More specifically, in the present embodiment, the first inverter 132 has its input threshold potential set to generally half the VCC, outputs a logical L when an input potential is higher than the input threshold potential, and outputs a logical H when the input potential is lower than the input threshold potential. Accordingly, when the potential at the connection node 116 rises and exceeds the input threshold potential, the output of the first inverter 132, in other words, the logical value of the data signal changes to a logical L. Then, the input/output terminal I/O outputs a logical L, as memory data that is stored in the storage section 110.

Next, by controlling the potentials on the two ends of the storage section 110 and at the connection node 116 based on the potential of an output of the first inverter 132, memory data is re-stored in the storage section 110. First, after the potential at the connection node 116 has risen, the control section 200 changes the control signal R to a logical L, thereby making the p-type MOS transistor 124 and the n-type MOS transistor 126 nonconductive. By this, the potential difference generation section 120 is electrically cut off from the storage section 110.

Also, the control section 200 changes the control signal W to a logical H, thereby making the transfer gates 142 and 144 conductive. By this, the output of the first inverter 132 is electrically connected to the two ends of the storage section 110. Accordingly, the potentials on one end of the first ferroelectric capacitor 112 and the other end of the second ferroelectric capacitor 114 become to be generally the same potential as the potential of the output of the first inverter 132, in other words, 0V.

In the meantime, when the control signal W changes to a logical H, the second inverter 134 outputs an inversion data signal in which the data signal outputted from the first inverter 132 is inverted. In other words, when the control signal H changes to a logical H, the output of the second inverter 134 changes from high impedance to a logical H. Accordingly, the potential on the input of the first inverter 132 and the potential at the connection node 116 rise from V0 to VCC. By this, a voltage −VCC is applied to the first ferroelectric capacitor 112, and a voltage VCC is applied to the second ferroelectric capacitor 114.

Referring to FIG. 3, as the voltage −VCC is applied to the first ferroelectric capacitor 112, the hysteresis characteristic moves from point B to point E. Also, as the voltage VCC is applied to the second ferroelectric capacitor 114, the hysteresis characteristic moves from point D to point F. Accordingly, “1” is re-written in the first ferroelectric capacitor 112, and “0” in the second ferroelectric capacitor 114. Also, at the time of writing, the latch section 130 keeps retaining the judgment result judged at the time of judgment, in other words, the logical value on the output of the first inverter 132 as it is.

Next, after the memory data has been stored again in the storage section 110, the control section 200 changes the control signal W to a logical L. By this, the two ends of the storage section 110 are electrically cut off from the output of the first inverter 132, and therefore the two ends of the storage section 110 and the connection node 116 are naturally discharged. In other words, the potentials on the two ends of the storage section 110 and the connection node 116 gradually lower to 0V. Also, when the potentials on the two ends of the storage section 110 and the connection node 116 become to be lower than the input threshold potential of the first inverter 132, the output of the first inverter 132 changes to a logical H. Accordingly, the storage circuit 100 is brought to the standby state described above.

In reverse of the present embodiment, when “0” is written in the first ferroelectric capacitor 112, and “1” is written in the second ferroelectric capacitor 114, and when the control signal W changes to a logical H, the potentials on the two ends of the storage section 110 become to be VCC, and the potential at the connection node 116 changes from V1 to 0V (see dotted lines in FIG. 2). By this, a voltage VCC is applied to the first ferroelectric capacitor 112, and a voltage −VCC is applied to the second ferroelectric capacitor 114, such that “0” is re-written in the first ferroelectric capacitor 112, and “1” in the second ferroelectric capacitor 114.

Also, when desired memory data is to be stored in the storage section 110, in a state in which the storage section 110 is electrically cut off from the potential difference generation section 120, and also, the storage section 110 is electrically connected to the output of the first inverter 132, the potential on the input/output terminal I/O is maintained at 0V or VCC from outside. By this, depending on the potential on the input/output terminal I/O, potentials on the both ends of the first ferroelectric capacitor 112 and the second ferroelectric capacitor 114 are fixed, and desired memory data is stored in the storage section 110.

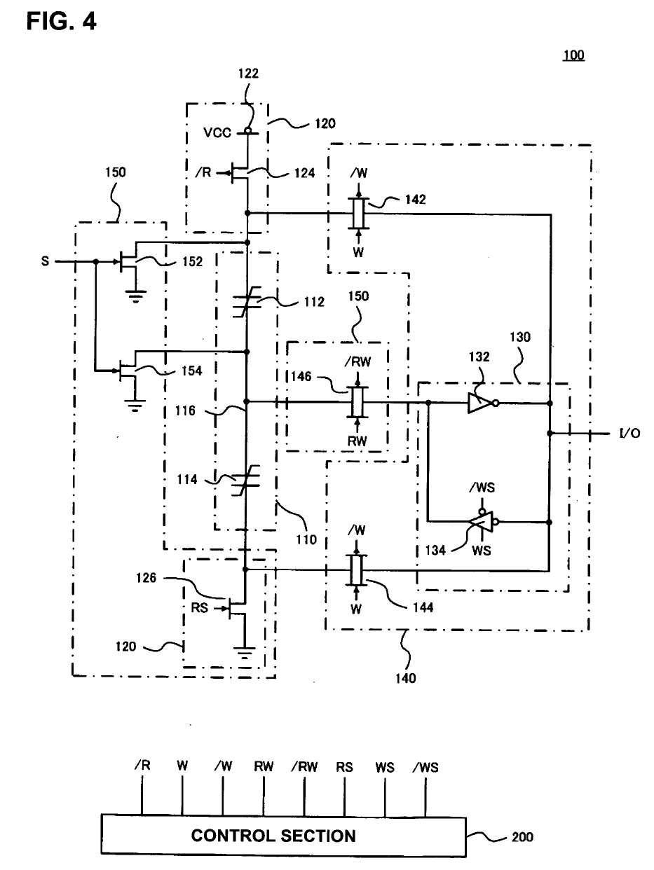

FIG. 4 is a diagram indicating a storage circuit 100 in accordance with a second embodiment. The storage circuit 100 in accordance with the second embodiment is described below, focusing on features different from those of the first embodiment. It is noted that components appended with the same reference numbers as those of the first embodiment have functions similar to those of the first embodiment.

Also, in the present embodiment, each control signal that includes a sign R is a control signal whose logical value at the time of judgment indicates a logical H. Also, each control signal that includes a sign W or S is a control signal whose logical value at the time of writing or standby indicates a logical H. Also, each control signal that includes a sign/ is a signal in which the logical value of the control signal without including the sign/is inverted.

The storage circuit 100 in accordance with the present embodiment is further equipped with a discharge section 150, in addition to the structure of the first embodiment. The discharge section 150 is an example of a device that brings the potential at the connection node 116 and the potentials on the two ends of the storage section 110 to the same potential, and is formed from a transfer gate 146, n-type MOS transistors 152 and 154, and an n-type MOS transistor 126. Among them, the n-type MOS transistor 126 composes a part of the potential difference generation section 120, and also composes a part of the discharge section 150.

The transfer gate 146 is provided between the output of the second inverter 134 and the connection node 116. The transfer gate 146 controls, based on potentials of the control signals W and /W supplied to its gate, as to whether or not the output of the second inverter 134 is to be electrically connected to the connection node 116.

The n-type MOS transistor 152 has its drain electrically connected to one end of the storage section 110, and its source grounded. Also, the n-type MOS transistor 154 has its drain electrically connected to the connection node 116, and its source grounded. Also, the control section 200 supplies a control signal S to the gates of the n-type MOS transistors 152 and 154, and a control signal RS to the gate of the n-type MOS transistor 126.

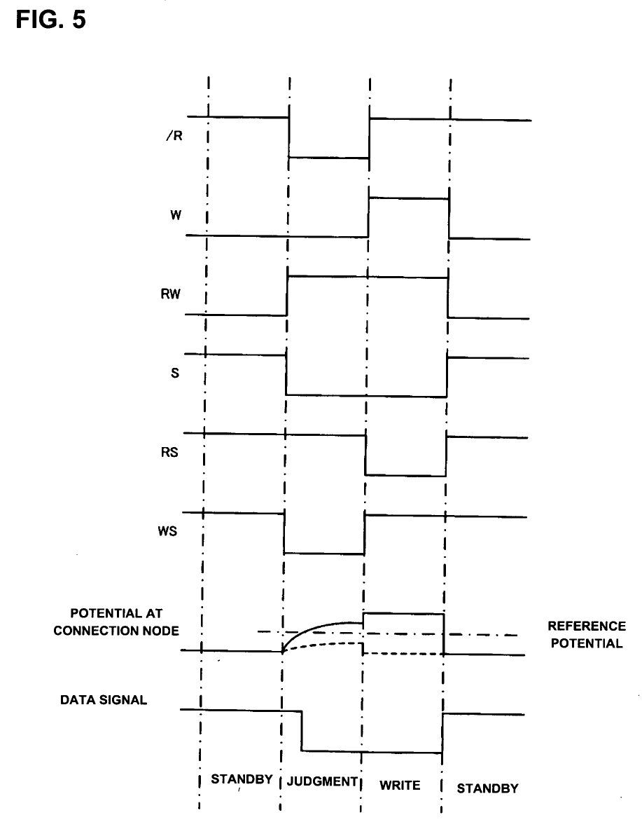

FIG. 5 is a timing chart indicating operations of the storage circuit 100 in accordance with the second embodiment. Referring to FIG. 4 and FIG. 5, the operations of the storage circuit 100 of the present embodiment are described. In the present embodiment, it is also assumed that “1” is stored in the first ferroelectric capacitor 112, and “0” is stored in the second ferroelectric capacitor 114. Also, in the present embodiment, the first ferroelectric capacitor 112 and the second ferroelectric capacitor 114 have generally the same hysteresis characteristics.

In a standby state, control signals W and RW indicate a logical L. Accordingly, the transfer gates 142 and 144 become nonconductive, such that the two ends of the storage section 110 are electrically cut off from the output of the first inverter 132. Also, because the transfer gate 146 becomes nonconductive, the connection node 116 is electrically cut off from the output of the second inverter 134.

Also, in the standby state, the control signals S, RS, and /R indicate a logical H. Accordingly, the n-type MOS transistors 126, 152 and 154 become conductive, and the p-type MOS transistor 124 becomes nonconductive, such that the two ends of the storage section 110 and the connection node 116 are grounded. In other words, the two ends of the storage section 110 and the connection node 116 become to be the same potential at 0V, such that no potential difference is generated across the both ends of the first ferroelectric capacitor 112 and the second ferroelectric capacitor 114.

At the time of judgment, the control signals RW and RS indicate a logical H, and the control signals S, /R and WS indicate a logical L. Accordingly, this results in a state in which the connection node 116 is electrically connected to the input of the first inverter 132, and the potential difference generation section 120 gives a potential difference VCC across the two ends of the storage section 110. Accordingly, at the time of judgment, the storage circuit 100 of the present embodiment operates in a similar manner as the first embodiment.

Also, at the time of writing, the control signals RW, /R and WS indicate a logical H, and the control signals S and RS indicate a logical L. Accordingly, this results in a state in which the connection node 116 is electrically connected to the input of the first inverter 132 and the output of the second inverter 134, the potential difference generation section 120 is electrically cut off from the storage section 110, an output of the first inverter 132 is supplied to the two ends of the storage section 110, and an output of the second inverter 134 is supplied to the connection node 116. Accordingly, at the time of writing also, the storage circuit 100 of the present embodiment operates in a similar manner as the first embodiment.

When the writing operation is completed, the control signals W and RW change to a logical L, such that the two ends of the storage section 110 are electrically cut off from the output of the first inverter 132, and the connection node 116 is electrically cut off from the output of the second inverter 134. Because the control signal WS that is supplied to the second inverter 134 in the standby state indicates a logical H, the judgment result retained by the latch section 130 at the time of writing is kept retained as it is even in the standby state.

Also, when the writing operation is completed, the control signals S and RS change to a logical H, such that the two ends of the storage section 110 and the connection node 116 become to be the same potential at 0V. In other words, the storage circuit 100 becomes to be in the same state as the standby state.

The embodiment examples and application examples described above with reference to the embodiments of the present invention may be appropriately combined depending on the usages, or may be used with changes and/or improvements added thereto. The present invention is not limited to the descriptions of the embodiments above. It is clear from the description in the scope of patent claims that modes created by such combinations, changes and/or improvements can be included in the technical scope of the present invention.

1. A storage circuit comprising:
a storage section having a first ferroelectric capacitor and a second ferroelectric capacitor that are connected to each other in series;
a potential difference generation section that gives a potential difference across both ends of the storage section; and
a judging section that judges memory data stored in the storage section based on a potential at a connection node between the first ferroelectric capacitor and the second ferroelectric capacitor when the potential difference is given across both ends.

2. A storage circuit according to claim 1, wherein the judging section judges the memory data by comparing a potential in a middle of the potential difference and a potential at the connection node.

3. A storage circuit according to claim 1, wherein the judging section has an inverter that receives the potential at the connection node as an input.

4. A storage circuit according to claim 1, further comprising a writing section that re-stores the memory data in the storage section, based on the memory data, by controlling the potentials on the both ends of the storage section and the connection node.

5. A storage circuit according to claim 4, wherein the writing section has a first inverter that receives the potential at the connection node as an input, and supplies an output to both ends of the storage section, and
comprising a second inverter that inverts the output of the first inverter, and supplies the output to the input of the first inverter.

6. A storage circuit according to claim 5, wherein the writing section is further equipped with a switch provided between the first inverter and the both ends of the storage section.

7. A storage circuit according to claim 1, further comprising a latch circuit that latches the memory data that the judging section has judged.

8. A storage circuit according to claim 1, further comprising a discharge section that brings the both ends of the storage section and the connection node to an identical potential.

9. A storage circuit according to claim 5, wherein the discharge section has a switch provided between the first inverter and the connection node.

10. A semiconductor device comprising the storage circuit recited in claim 1.

11. An electronic apparatus comprising the semiconductor device recited in claim 10.

12. A driving method for driving a storage circuit that is equipped with a storage section having a first ferroelectric capacitor and a second ferroelectric capacitor connected to each other in series, the driving method comprising:
a step of giving a potential difference across both ends of the storage section; and
a step of judging memory data stored in the storage section based on a potential at a connection node between the first ferroelectric capacitor and the second ferroelectric capacitor when the potential difference is given across the both ends.

13. A driving method according to claim 12, further comprising a step of re-storing the memory data in the storage section, based on the memory data judged, by controlling the potentials on the both ends of the storage section and the connection node.
